(19) United States
(12) Patent Application Publication
(10) Pub. No.: US 2006/0147059 A1
(43) Pub. Date: Jul. 6, 2006

(54) Smart volume adjusting method for a multi-media system

(75) Inventors: Guo-Qiang Tang, Taipei (TW); Ying-Zhen Tong, Taipei (TW); David Ho, Taipei (TW)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(73) Assignee: Inventec Appliances Corporation, Taipei (TW)

(21) Appl. No.: 11/187,429

(22) Filed: Jul. 22, 2005

(30) Foreign Application Priority Data
Dec. 30, 2004 (TW) 093141514

(51) Int. Cl. H03G 3/00

(52) U.S. Cl. 381/104

(57) ABSTRACT

A smart volume adjusting method for a multi-medium system is described, through which ears of a user of the multi-medium system may be protected and the problem that an initial volume is not suitable for hearing habit of the user when an audio playing device of the multi-medium system is connected may be overcome. In the method, type of the audio playing device used by the user is identified based on resistance of the audio playing device since each audio playing device has its specific resistance. Further, a customary volume with respect to the user is recorded and then taken as a reference to dynamically adjust a volume output in the multi-medium system.

### BACKGROUND OF THE INVENTION

1. Field of the Invention

The present invention relates to a smart volume adjusting method for a multi-medium system, and particularly to a smart volume adjusting method by which a volume playing device type may be determined and a customary volume with respect to a user may be recorded so that a dynamically adjusted volume output may be obtained.

2. Descriptions of the Related Art

Audio playing devices have been widely used with multi-media. The users of such audio playing devices may unavoidably have the problem that switching among several audio playing devices may cause a non-suitable volume at an initial stage with respect to his or her hearing habit. In using such audio playing devices, loudspeakers, earphones and the like may be used. When a loudspeaker is used, the volume is likely to be adjusted relatively louder. When the earphone is used, the user may feel uncomfortable and even be hurt in the eardrum with respect to the same volume. In the case that the earphone is first used and the loudspeaker is then used, the user generally desires to adjust the played volume louder.

The Third National Health and Nutrition Examination Survey has published a hearing research associated report, which is conducted on youngsters of six to nineteen years old over an eight-year period, indicating youngsters of up to 12.5% were shown have NITS (Noise-induced Hearing Threshold Shifts) in a hearing examination in the US, representing they had at least one time exposed to an excess noise environment which is detrimental to the ears.

Therefore, there is a need to provide a method of dynamically adjusting a volume output of an audio playing device connected to a multi-medium system based on the type of the used audio playing device.

### SUMMARY OF THE INVENTION

It is, therefore, an object of the present invention to provide a smart volume adjusting method for a multi-medium system so that a user's ears may be protected and the problem of volume not suitable to the user's hearing habit occurred at an initial stage when an audio playing device is connected to the multi-medium system.

It is another object of the present invention to provide a smart volume adjusting method for a multi-medium system by which volume of the multi-medium system may be automatically adjusted based on type of the audio playing device connected thereto.

It is still another object of the present invention to provide a smart volume adjusting method for a multi-medium system by which a customary volume for a user may be recorded and thus a volume output may be dynamically adjusted.

To achieve the above objects, the smart volume adjusting method for a multi-media system according to the present invention comprises the steps of providing an audio playing device database in the multi-medium system, wherein the audio playing device database comprises resistance values, user's last time volume settings and predetermined volume values of a plurality of audio playing devices recorded in the audio playing device database; detecting a resistance value of the audio playing device connected to the multi-medium system; determining if the audio playing device is a predefined type of audio playing device recorded in the audio playing device database by comparing the detected resistance value with the resistance values recorded in the audio playing device database; if not the predetermined type, adjusting the volume of the multi-medium system to be minimum and recording the audio playing device and the resistance value thereof into the audio playing device database so that the audio playing device becomes among the plurality of audio playing devices in the audio playing device database; if yes, checking if a user's last time volume setting of the audio playing device has been recorded in the audio playing device database; if the user's last time volume setting is not available, determining the audio playing device is connected to the multi-medium system for the first time and adjusting the multi-medium system to have a predetermined volume based on the audio playing device database; if the user's last time volume setting is determined as available, determining the audio playing device has been connected to the multi-medium system for more than one time and adjusting the volume of the multi-medium system to be the user's last time volume setting based on the audio playing device database; detecting if the user has adjusted the volume of the audio playing device; if no, continuing the step of detecting step if the user has adjusted the volume of the audio playing device; if yes, recording the new user's volume setting into the audio playing device database in replace of the original user's last time volume setting; and going back to the step of detecting the resistance value of the audio playing device connected to the multi-medium system.

To enable those skilled in the art to further understand concepts, realizations and functions of the present invention, the present invention will be described in more detail as follows with reference to the accompanying drawings.

### BRIEF DESCRIPTION OF THE DRAWINGS

FIG. 1 shows a flowchart illustrating a smart volume adjusting method for a multi-medium system according to the present invention; and

FIG. 2 shows a circuit diagram for realization of the smart volume adjusting method for a multi-medium system according to an embodiment of the present invention.

### DETAILED DESCRIPTION OF THE INVENTION

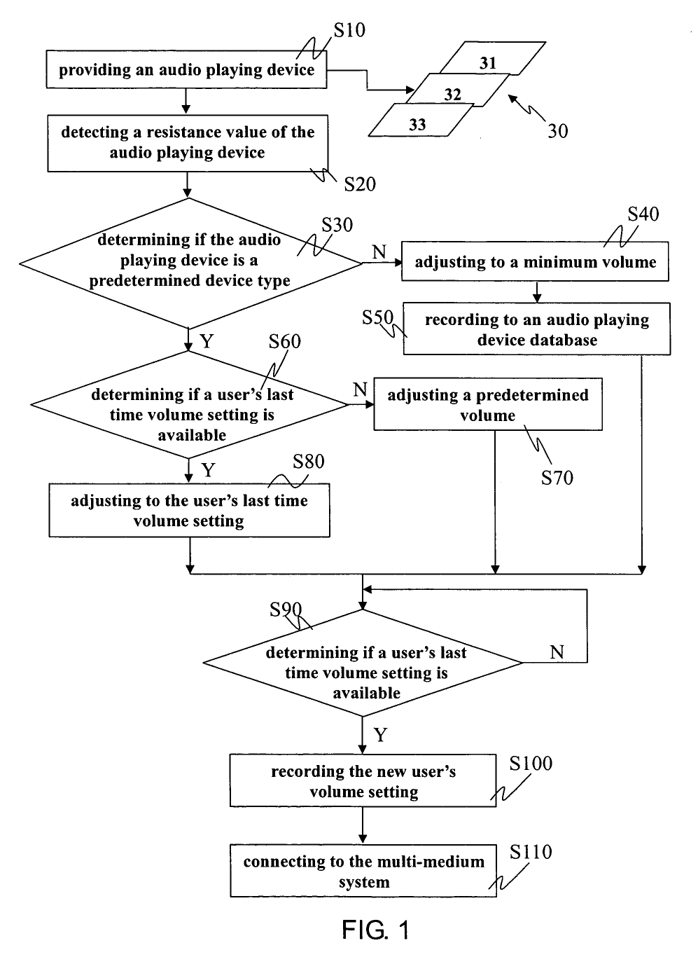

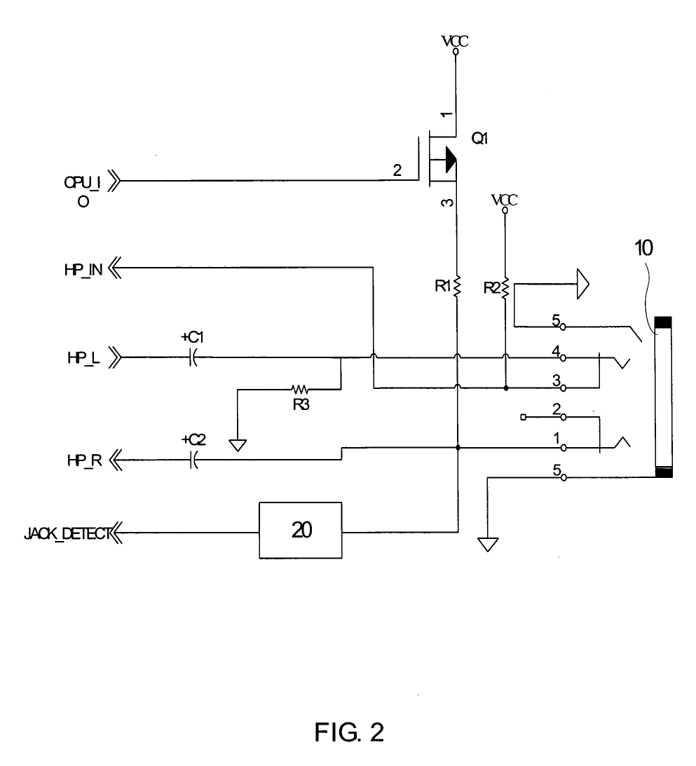

FIG. 1 shows a flowchart illustrating a smart volume adjusting method for a multi-media system according to the present invention. FIG. 2 shows a circuit diagram for realization of the smart volume switching method for a multi-media system according to an embodiment of the present invention. In the method, an audio playing device database 30 is first provided in a chip, such as a memory device, of the multi-medium system (S10). Referring to FIG. 1 and FIG. 2, the audio playing device database 30 comprises resistance values 31, user's last time volume settings 32 and predetermined volume values 33 of the plurality of volume playing devices recorded in the database 30. When an audio playing device is connected to the multi-medium system, a resistance value of the audio playing device is detected (S20). For example, when a plug of an earphone is inserted into an earphone jack 10 (PHONE_JACK) on an audio card of the multi-medium system, a pin HP_IN of the audio card will have a variation in level and thus turn a pin CPU_IO of the audio card from a low level to a high level and Q1 is thus turned on. As generally known in the field, different audio playing devices have different resistance values with respect to ground at their right or left channels. For example, the resistance values of an earphone and a speaker are 32 ohms and 24 ohms, respectively. Owing to the different resistance values of audio playing devices, voltage at a connection point pin1 of the earphone jack 10 (PHONE_JACK) varies with the connected audio playing device. The voltage is conversed by an analog-to-digital converter (ADC) chip 20 (ADC_CHIP) into a detection signal JACK_DETECT, which is then transmitted to the CPU of the multi-medium system. Then, the level of the pin CPU_IO is lowered and Q1 is thus cut off, preventing input voltage (VCC) from having an influence on the outputted audio signal. In the CPU of the multi-medium system, the signal JACK_DETECT representing a resistance value of the used audio playing device is compared with all resistance values 31 recorded in the audio playing device database 30 so as to determine if the used audio playing device is a predefined type of audio playing device (S30). If not, the CPU of the multi-medium system adjusts the played volume to be minimum (S40). Further, the audio playing device type and its resistance value are recorded onto the audio playing device database 30 so that the audio playing device becomes among the predefined audio playing devices (S50). If yes, the CPU further checks if the user's last time volume setting 32 of the audio playing device is available (S60). If not, the audio playing device is determined as being used with the multi-medium system for the first time and the CPU adjusts the played volume to be a predetermined volume 33 based on the audio playing device database 30 (S70). If yes, the audio playing device is determined as having been used with the multi-medium system for more than one time and the CPU adjusts the played volume of the multi-medium system to the user's last time volume setting 32 (S80). Further, the CPU may detect if the user has adjusted the volume of the audio playing device. If no, the detection continues. Otherwise, the next step is executed (S90). When the user is determined as having adjusted the volume of the audio playing device, the CPU records the new user's volume setting into the audio playing device database in replace of the user's last time volume setting 32 (S100). If another audio playing device is connected to the multi-medium system, the process goes back to S20 (S110). The above steps can be written as software.

Furthermore, another method may be alternatively used, which is simple and saves cost. When the earphone plug of the audio playing device is inserted into the earphone jack 10 (PHONE_JACK) of the multi-medium system, the pin HP_IN will have a level change. At this time, the volume of the multi-medium is adjusted lower no matter which audio playing device is used. The above steps can also be written as software executed by a central process (CPU) and stored in a chip such as a memory device.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A volume adjusting method for a multi-media system in which volume of the multi-medium system is automatically adjusted into a proper value when an audio playing device is connected to the multi-medium system by a user, comprising the steps of:
providing an audio playing device database in the multi-medium system, wherein the audio playing device database comprises resistance values, user's last time volume settings and predetermined volume values of a plurality of audio playing devices recorded in the audio playing device database;
detecting a resistance value of the audio playing device connected to the multi-medium system;
determining whether the audio playing device is a predefined type of audio playing device recorded in the audio playing device database by comparing the detected resistance value with the resistance values recorded in the audio playing device database;
if not the predetermined type, adjusting the volume of the multi-medium system to be minimum and recording the audio playing device and the resistance value thereof into the audio playing device database so that the audio playing device becomes among the plurality of audio playing devices in the audio playing device database;
if yes, checking if a user's last time volume setting of the audio playing device has been recorded in the audio playing device database;
if the user's last time volume setting is not available, determining the audio playing device is connected to the multi-medium system for the first time and adjusting the multi-medium system to have a predetermined volume based on the audio playing device database;
if the user's last time volume setting is determined as available, determining the audio playing device has been connected to the multi-medium system for more than one time and adjusting the volume of the multi-medium system to be the user's last time volume setting based on the audio playing device database;
detecting whether the user has adjusted the volume of the audio playing device;
if no, continuing the step of detecting step if the user has adjusted the volume of the audio playing device;
if yes, recording the new user's volume setting into the audio playing device database in replace of the original user's last time volume setting; and
going back to the step of detecting the resistance value of the audio playing device connected to the multi-medium system.

2. The method according to claim 1, wherein the audio playing device database and the steps are written as software and stored in the multi-medium system and executed by a central process unit (CPU) of the multi-medium system.

3. The method according to claim 2, wherein the software is stored in a chip of the multi-medium system.

4. The method according to claim 3, wherein the chip is a memory device.

5. The method according to claim 1, wherein each of the audio playing devices has a unique resistance value causing a unique voltage conversed into a unique digital signal by an ADC chip, wherein the digital signal is transmitted to a unit for executing the steps in the multi-medium system.

6. A smart volume adjusting method for a multi-media system in which volume of the multi-medium system is automatically adjusted into a proper value when an audio playing device is connected to the multi-medium system by a user, comprising the step of adjusting the multi-medium system to have a lower volume irrespective of type of the audio playing device.

7. The method according to claim 6, wherein the step is written as software and executed by a central process unit (CPU) of the multi-medium system.

8. The method according to claim 7, the software is stored in a chip of the multi-medium system.

9. The method according to claim 8, wherein the chip is a memory device.

10. The method according to claim 6, wherein each of the audio playing devices has a unique resistance value causing a unique voltage conversed into a unique digital signal by an ADC chip, wherein the digital signal is transmitted to a unit for executing the steps in the multi-medium system.
